(19) United States
(12) Patent Application Publication
(10) Pub. No.: US 2006/0284266 A1
(43) Pub. Date: Dec. 21, 2006

(54) High voltage N-channel LDMOS devices built in a deep submicron CMOS process

(75) Inventor: Gregorio Spadea, Saratoga, CA (US)

Correspondence Address: BERKELEY LAW & TECHNOLOGY GROUP, 1700NW 167TH PLACE, SUITE 240, BEAVERTON, OR, 97006, US

(73) Assignees: Stellar Kinetics LLC; Virtual Silicon Technology, Inc.

(21) Appl. No.: 11/510,044

(22) Filed: Aug. 25, 2006

Related U.S. Application Data
(62) Division of application No. 10/147,229, filed on May 15, 2002.
(60) Provisional application No. 60/291,457, filed on May 15, 2001.

(51) Int. Cl. H01L 29/76

(52) U.S. Cl. 257/389

(57) ABSTRACT

A novel Laterally Diffused NMOS device is described. With proper design the drain terminal of this device can be raised to a much higher voltage that the maximum allowed gate voltage of the CMOS technology into which the device is built. The device can be built in a conventional deep submicron CMOS technology as used for the 0.25 um node and beyond without additional masks or dedicated processing steps. When a deep N-well mask and ion implantation is added to the process, the device can be operated with a body voltage positive above ground. This device can be used like a conventional LDMOS for circuits which require a device capable of switching voltages which exceed the rating of conventional CMOS devices by using as low voltage input signal.

### RELATED APPLICATIONS

This application hereby claims the benefit of provisional application No. 60/291,457, filed on May 15, 2001.

### BACKGROUND

1. Field

The present disclosure relates to silicon devices. In particular, the present disclosure relates to a novel and improved High Voltage N-channel LDMOS Device Built in a Deep Submicron CMOS Process.

2. Background

In deep submicron CMOS processes using conventional designs of MOS transistors, a maximum voltage can be applied to a drain of an N-channel or a P-channel device. The voltage applied to the drain of the device is limited by the maximum voltage that can be applied between the gate and the drain of the device. Degradation of the gate oxide under high electric fields during the operating life of the devices limits the voltage that may be applied between the gate and the drain of the device.

The electric field applied between the gate and the drain is usually limited to less than 7 MV/cm. For instance in the 0.18 um CMOS technology, a gate oxide thickness of 3.5-4.0 nm is used. For a gate oxide of this thickness, the maximum voltage of the electric field is limited to +2.7V for the N-channel device and −2.7V for the P-channel device. As the technology is scaled down, the voltage of the electric field also reduces. For example, the voltage of the electric field is reduced to +/−1.5V for N-channel and P-channel devices in the 0.13 um technology.

In addition to conventional CMOS devices, applications in other technologies would benefit from MOS devices which can sustain a much higher voltage on the drain terminal and which can be fabricated with no or a minimal number of additional processing steps. An example of an application in another technology that would benefit from such a MOS device is the integration of non-volatile memory devices based on the floating gate technology. Integration in these memories typically requires devices that can sustain a voltage on the order of 15V for programming or erasing the non-volatile memory cell. Other examples of applications include the integration of analog functions where the availability of higher voltage devices increases the large-signal voltage swing, or output drivers which can be driven by the low voltage conventional CMOS logic devices but can switch a much higher voltage on their outputs.

In principle, it is possible, using a deep submicron CMOS technology, to make high voltage CMOS devices of a conventional device design by using dedicated drain and well diffusions and a gate oxide of the appropriate thickness. The thickness of the gate oxide in such a device is 20-30 nm for a 15V operation, compared to the 3-4 nm used in the conventional CMOS devices in the 0.8 um technology. This approach increases significantly the process complexity and the cost of the wafers.

Laterally Diffused MOS (LDMOS) devices have been used for quite some time. Prior art LDMOS devices are typically integrated in a BiCMOS process where all the devices are built in an epitaxial layer and where use is made of the “resurf” principle which reduces the surface fields.

A cross-sectional view of a typical N-channel LDMOS 100 is shown schematically in FIG. 1. In FIG. 1, it is assumed a conventional LOCOS field oxide 150, a diffused P-isolation 105 and a diffused P-diffusion (P-body) 110, which can be self-aligned or not to the Poly Gate, are used. By using the appropriate thickness and doping of N-epi layer 120, the resurf effect reduces the electrical field at the vertical junction 160 formed by the P-isolation 105 and the N-epi layer 120 below the value at the junction 125 of the N-epi layer 120 and the P-substrate 130.

At the same time, the doping of the N-epi layer 120 in region 125 under the field oxide is chosen in such a way that the region 140 is depleted of mobile carriers at a drain voltage that is about equal to the maximum voltage which can be applied across the gate oxide without affecting its reliability.

Any further increase of the drain voltage is not going to change the electric field across the gate oxide and the maximum drain voltage becomes now limited by the breakdown voltage of the drain junction.

The “resurf” effect makes it possible to have the breakdown voltage of the drain junction be equal to the breakdown voltage of the plane of junction 125 between the N-epi layer 120 and the P-substrate 130.

### SUMMARY

An advance in the art is achieved by a novel high voltage N-Channel LDMOS device built in a deep submicron CMOS process. With proper design, the drain terminal of an N-channel LDMOS device can be raised to a much higher voltage than the maximum allowed gate voltage of the CMOS technology into which the device is built. The LDMOS device can be built in a conventional deep submicron CMOS technology as used for the 0.25 um node and beyond without additional masks or dedicated processing steps.

When a deep N-well mask and ion implantation is added to the process, the LDMOS device can be operated with a body voltage positive above ground. The LDMOS device can be used like a conventional LDMOS for circuits which require a device capable of switching voltages which exceed the rating of conventional CMOS devices by using as low voltage input signal.

### BRIEF DESCRIPTION OF THE DRAWINGS

The features, objects, and advantages of the present invention will become more apparent from the detailed description set forth below when taken in conjunction with the drawings in which like reference characters identify correspondingly throughout and wherein:

FIG. 1 is a schematic of a prior art device;

FIG. 2 is a schematic of one aspect of a disclosed device; and

FIG. 3 is a schematic of another aspect of a disclosed device.

### DETAILED DESCRIPTION

Persons of ordinary skill in the art will realize that the following description is illustrative only and not in any way limiting. Other modifications and improvements of the invention will readily suggest themselves to such skilled persons having the benefit of this disclosure.

Deep submicron CMOS processes, starting from the 0.25 um technology, differ from older generation processes in several areas. One difference is that the field oxide isolation is done using the Shallow Trench Isolation (STI), where a trench is etched in the silicon substrate which is then filled with an insulator, typically made of silicon dioxide. The STI process produces an almost vertical interface between the silicon and the isolation oxide that is fully recessed below the surface.

A second difference is that two masks are used for defining a P-Well and a N-Well. The doping profiles for the masks are set to the appropriate shapes by using multiple ion implantations. The use of two masks for defining the wells allows the definition of surface areas. The surface areas are protected during the well implants. The result of the protection of the surface areas is that the well implants to be lightly doped as the starting material. In this process the wells have a concentration of approximately 1E15 cm-3 compared to the conventional surface concentration of the P and N wells which are typically two order of magnitude greater. These new processes make it possible to create novel high voltage devices. These novel high voltage device require no or very minimal additional processing steps.

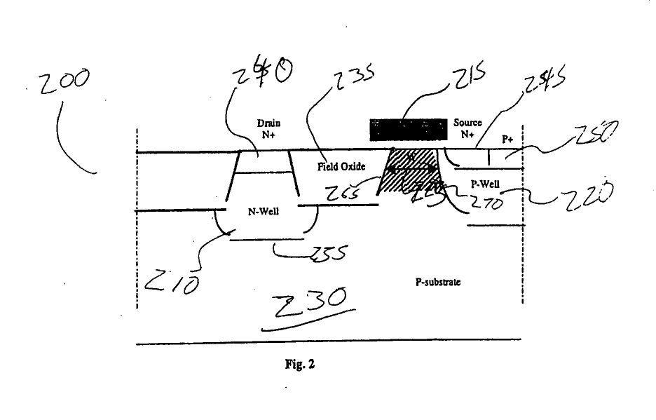

FIG. 2 shows the implementations of a high voltage N-channel LDMOS 200 produced in accordance with the present invention. If the width, W, of the region 225 under the gate 215, is such that the region 225 is fully depleted when a drain reverse bias equal to the maximum voltage difference which can be tolerated across the gate oxide (for instance 2.7V for the 0.18 um technology), the drain voltage can be further increased without changing the electrical field in the gate oxide and the drain voltage limitation is the breakdown voltage of the N-well 210 to P-substrate 230 junction 235, which is typically above 20V.

Assuming a P-substrate 230 concentration of 1E15 and an abrupt P-well 220 to P-substrate 230 junction 275 model, the region 225 is fully depleted at 2.7V if width, W, is equal to 1.5 um.

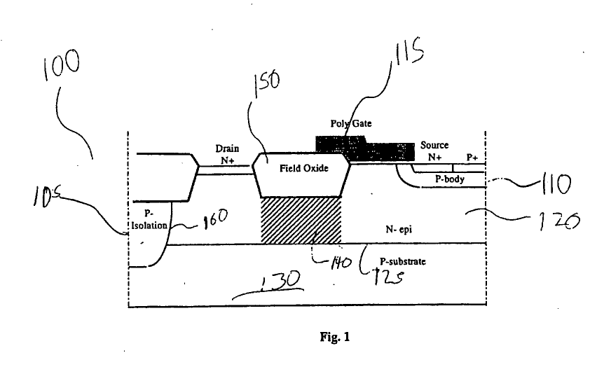

The mechanism is the same used in the conventional LDMOS device depicted in FIG. 1, except that there the depleted region 140 is bound by two horizontal surfaces, the bottom surface of the LOCOS isolation and junction 125 of N-epi layer 120 and P-substrate 130. In LDMOS device 200, shown in FIG. 2, the depleted region is bound by two vertical surfaces, the STI vertical wall 265 and the sidewall 270 of the P-well 220.

The LDMOS device 200 can be built in a conventional deep submicron process without any additional processing steps, changes to the substrate material, or changes to the doping profiles of the wells used in the conventional low voltage CMOS devices. In accordance with this invention, it is possible to create, for instance, in a conventional 0.18 um technology, N-channel LDMOS devices which can easily sustain a drain voltage above 15V and can be switched with a gate voltage which is within the maximum voltage limit allowed by the technology.

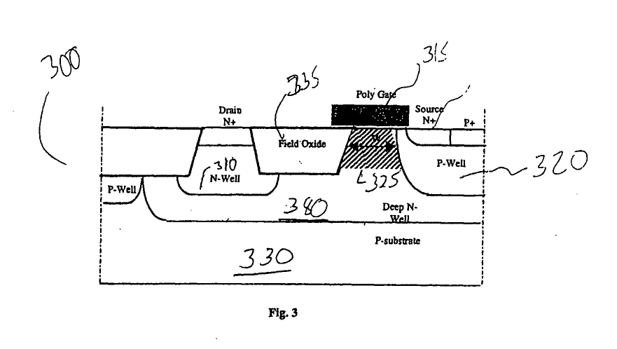

Referring now to FIG. 3, the P-well 320 and N-well 310 are formed by multiple implants of Boron and Phosphorus species with different energies in deep submicron technologies. These selective implants are usually performed after the shallow trench isolation process is completed. Since it is necessary to provide an adequate amount of dopant underneath the field oxide 335, at least one of these implants of N-well 310 or P-well 320 is done using very high energies, such as 200-300 KeV for Boron and 600-800 KeV for Phosphorus. These implants of N-well 310 or P-well 320 are done using ion implanters that can be operated up to 1 MeV and above.

Ion implanters are common in the art and readily available. Therefore, ion implanters are readily available for use in deep submicron technologies to introduce an additional high energy implant, usually called the Deep N-well 380. The energy implants can be done using energies of 1.0-1.2 MeV. Deep N-well 380, when placed underneath the conventional CMOS devices, does not affect the electrical characteristics of the CMOS devices. However, deep N-well 380 allows the formation of CMOS devices which are electrically isolated from the P-substrate 330. Deep N-well 380 may be used for isolating analog circuits made with the conventional CMOS devices from the substrate 330.

The device 300 can take advantage of a Deep N-well 380. In device 300, it is now possible to raise the body (P-well 320) potential positive above the P-substrate 320, which is usually grounded.

The previous description of various embodiments, which include preferred embodiments, is provided to enable any person skilled in the art to make or use the present invention. The various modifications to these embodiments will be readily apparent to those skilled in the art, and the generic principles defined herein may be applied to other embodiments without the use of the inventive faculty. Thus, the present disclosure is not intended to be limited to the embodiments shown herein but is to be accorded the widest scope consistent with the principles and novel features disclosed herein.

1-18. (canceled)

19. A method for manufacturing a high voltage Laterally Diffused MOS comprising:
defining a silicon substrate; and
applying a field oxide isolation using Shallow Trench Isolation (STI).

20. The method of claim 19 further comprising:
defining a P-well using a first mask; and
defining a N-well using a second mask.

21. The method of claim 20 further comprising: setting doping profiles of said first and second masks to appropriate shapes using a plurality of ion implants.

22. The method of claim 21 further comprising: protecting surface areas during said plurality of ion implants.

23. The method of claim 19 further comprising: defining a deep n-well between said silicon substrate and said isolation oxide field.

24. A method of making a metal oxide semiconductor device on a doped substrate including semiconductor material having a predetermined conductivity type, the method comprising:
forming a source region comprising a first conductivity type semiconductor material in said substrate;
forming a drain region comprising a second conductivity type semiconductor material in said substrate, said first conductivity type being different from said second conductivity type; and
etching a trench region located between said source and drain regions using a shallow trench isolation technique in said substrate, said trench region including at least one substantially vertical sidewall, said trench region including an isolation field oxide therein, the at least one vertical sidewall of said trench region being separated from said source region sufficiently to define a depletion region therebetween wherein said depletion region comprises the semiconductor material of said substrate.

25. The method defined in claim 24 further comprising depositing a gate oxide layer substantially overlying at least a portion of said trench region and said depletion region.

26. The method as defined in claim 25, wherein said depletion region exhibits a width W to allow full depletion upon application of a drain reverse bias voltage substantially equal to a maximum voltage difference that can be tolerated by the gate oxide layer.

27. A method of making a metal oxide semiconductor device on a doped substrate including semiconductor material having a predetermined conductivity type, the method comprising:
forming a deep well region formed in said substrate comprising a semiconductor material having a conductivity type opposite to said predetermined conductivity type;
forming a source region comprising a first conductivity type semiconductor material in said deep well region;
forming a drain region comprising a second conductivity type semiconductor material in said deep well region, said first conductivity type being different from said second conductivity type; and
etching a trench region located between said source and drain regions using a shallow trench isolation technique in said deep well region, said trench region including at least one substantially vertical sidewall, said trench region including an isolation field oxide therein, the at least one vertical sidewall of said trench region being separated from said source region sufficiently to define a depletion region therebetween wherein said depletion region comprises the semiconductor material of said substrate.

28. The method defined in claim 27 further comprising depositing a gate oxide layer substantially overlying at least a portion of said trench region and said depletion region.

29. The method as defined in claim 28, wherein said depletion region exhibits a width W to allow full depletion upon application of a drain reverse bias voltage substantially equal to a maximum voltage difference that can be tolerated by the gate oxide layer.
